(19) United States
(12) Patent Application Publication
(10) Pub. No.: US 2012/0186635 A1
(43) Pub. Date: Jul. 26, 2012

(54) HIGH EFFICIENCY ELECTROMAGNETIC RADIATION COLLECTION METHOD AND DEVICE

(76) Inventors: Craig D. Eastman, Edmonton (CA); Douglas R. Hole, Edmonton (CA)

(21) Appl. No.: 13/359,269

(22) Filed: Jan. 26, 2012

Related U.S. Application Data
(60) Provisional application No. 61/461,986, filed on Jan. 26, 2011.

(51) Int. Cl. H01L 31/02; B82Y 99/00

(52) U.S. Cl. 136/252; 977/948

(57) ABSTRACT

Devices and methods are described for more effectively collecting solar energy, including both visible and non-visible electromagnetic radiation to be converted into electrical energy. For example, a nanotube/nanowire device, comprising an electrical contact layer, semi-conductive layer, insulating layer, source electrode, drain electrode and semi-conducting nanotubes/nanowires can be used to collect solar energy from the UV to the infrared electromagnetic spectrum. Another example comprises a device that is capable of adjusting its frequency response to maximize power output according to the wavelength of electromagnetic radiation present. These devices and related methods are useful, for example, to provide an alternative electrical energy source, harness unused renewable energy, reduce carbon dioxide emissions, counteract global warming, and provide a carbon neutral energy source. The devices and methods are also useful, for example, to cool the interior of buildings, automobiles, airplanes, electronic devices/systems, etc.

### Claim Of Priority

The present application claims priority to U.S. Provisional Patent Application No. 61/461,986 filed Jan. 26, 2011, which is incorporated herein by reference in its entirety.

### FIELD OF THE INVENTION

The invention generally relates to methods and devices to collect solar energy over a broadened portion of the electromagnetic spectrum and convert it to electrical energy. The methods and devices include, but are not limited to, nanotubes and nanowires, such as carbon-based nanotubes and nanowires, used to collect solar energy and convert it to electrical energy.

### BACKGROUND OF THE INVENTION

It is estimated that by 2040 the annual global consumption of power will be equivalent to 900 quadrillion Btu (Quads), or an average power of 30 Terawatts (TW) or 30×10¹² Watts (See Aydil, E. S., Nanomaterials for Solar Cells, Naotechnology Law & Business, 2007, p. 275.) To supply half of this requirement, or 15 TW, with nuclear power would require the construction of an average sized nuclear power plant (1000 MW) everyday for the next 41 years.

Most of the current global power demand is met by the combustion of fossil fuels and nuclear reaction of fissile materials. Table 1 provides known fossil fuel reserves, and Table 2 provides known reserves of fissionable material.

TABLE 1
Fossil Fuel Reserves.

| Type | ExaJoules-EJ (10¹⁸ J) | Published Date |
|---|---|---|
| Methane Clathrate (hydrate) | 100,000 | 1998 |
| Coal | 39,000 | 2002 |
| Gas | 15,700 | 2002 |
| Liquefied Gas | 2,300 | 2002 |
| Shale | 16,000 | estimated |

TABLE 2
Fissionable Material Reserves.

| Fissionable Material | ExaJoules-EJ (10¹⁸ J) | Published Date |
|---|---|---|
| ²³⁵U | 2,600 | 2008 |
| ²³⁸U | 320,000 | 2008 |
| ²³²Th | 11,000 | 2008 |

According to the Oil & Gas Journal (OGJ), the worldwide proven reserves of conventional oil increased to 1.34 trillion barrels (8174 EJ) with worldwide natural gas reserves increasing to 6,254 trillion cubic feet (6254 EJ) in 2008. In September 2006, OPEC estimated that of the Earth's producible potential of 5.7 trillion barrels of oil, only one trillion barrels (or 18%) have been produced and what remains is estimated to last for another 140 years at current production rates. (See Vital, T., “Industry Surveys: Oil & Gas: Production and Marketing”, Standard & Poors, Aug. 27, 2009.) The consulting firm International Energy Associates estimates that of the remaining 4.7 trillion barrels of oil, extraction of about three quarters of it, or 3.5 trillion barrels of oil, will depend on the development of new technologies. Energy consulting firm PFC Energy estimates that given current technology the international petroleum system will find it difficult to surpass an oil production rate of more than 100 million barrels per day.

This is of near-term concern: although the consumption of oil as of July 2009 according to IHS Global Insight (an independent economic forecaster) had contracted to 83.68 million barrels per day, it is forecast to reach 90.25 million barrels per day in 2015 and to 100 million barrels per day by 2035. Assuming that each barrel of oil is equivalent to 6 GJ, the daily energy consumption is equivalent to 0.5021 EJ in 2009, 0.54150 EJ in 2015 and 0.6000 EJ in 2035.

There has been considerable debate regarding these long term reserves of oil and natural gas, as well as other fossil fuels. Regardless, someday a shortage of oil and gas, and even coal, will eventually occur, and it seems likely that it will occur at least by 2050 due to population growth and economic development. (See Skov, A. M., “World Energy Beyond 2050”, Society of Petroleum Engineers, SPE 77506, 2002, p. 12.)

Moreover, globally, the largest source of anthropogenic Green House Gas (GHG) emissions is CO₂ from the combustion of fossil fuels—around 75% of total GHG emissions covered under the Kyoto Protocol. (See Balat, M., Influence of Coal as an Energy Source on Environmental Pollution, Energy Sources, Part A, vol.29, 2007, p. 581-589.) Coal supplies 23% of the world's primary energy and around 60% of coal used globally is for electricity production. For example, the province of Alberta, Canada, relies on coal for 89-90% of its electricity.

In conclusion, humans consume an enormous amount of energy compared to what can be obtained from any one of the renewable sources—with the exception of sunlight. The sun converts 700 million tones of hydrogen per second to 695 million tones of Helium per second. This difference in mass is converted into electromagnetic energy primarily in the infrared to ultraviolet range with large amounts of energy transmitted to Earth. Each square meter of the Earth's surface has the potential to produce 1,000 watts of energy. The total amount of energy emitted by the Sun is so enormous that in less than one hour the energy needs for humanity would be met for one year. For example, with solar cells that are 15% efficient, an area 100×100 miles (10,000 square miles) in the southwest United States could provide all the electrical energy for the United States as of 2006.

### SUMMARY OF THE INVENTION

Increased efficiencies and broadband collection could dramatically reduce the geographic footprint needed to collect solar power sufficient to meet mankind's increasing needs. Additionally, existing power grids could be decentralized and complimented through application and integration of efficient, broadband solar collection technologies at a variety of locations.

Accordingly, provided herein are methods and devices for converting solar energy, such as electromagnetic energies in the infrared and ultraviolet wavelengths, into electrical energy. In some instances, the devices comprise elongated nanostructures such as nanotubes or nanowires. The elongated nanostructures can be connected on opposite ends to source and drain electrodes. The impingement of electromagnetic radiation, such as electromagnetic radiation in the infrared and ultraviolet wavelengths, can cause holes and free electrons to form in the elongated nanostructures that are collected as electrical current at the electrodes.

The range of electromagnetic frequencies to which the devices respond can be adjusted or tuned, for example, so that the devices are responsive to electromagnetic radiation including ultraviolet radiation, infrared radiation, visible light, and radiation from the ultraviolet to the infrared spectrums. Adjusting or tuning of the devices' responses to electromagnetic radiation of varying frequencies and energies can be accomplished, for example, by altering the physical shape and size of the elongated nanostructures, altering the nanostructures' compositions, physically stressing or straining the nanostructures, providing bandgap-adjusting electrical fields, altering the nanostructures' gate voltages, altering the compositions of the nanostructures' gates, and so forth as more fully explained herein. As a general matter, the various known methods to alter the nanostructures' bandgaps can be used to adjust or tune the nanostructures to be responsive to electromagnetic radiation of differing frequencies. In some instances, the devices can include nanostructures, or regions of nanostructures, that are adjusted or tuned to respond to different electromagnetic frequencies, such as ultraviolet, visible, and infrared frequencies. In this way, a device can be made to respond to a wider range of electromagnetic frequencies and energies and therefore more efficiently convert solar energy to electrical energy by including nanostructures adjusted or tuned to respond to different frequencies of electromagnetic radiation. In some instances, the devices also can be dynamically adjusted or tuned so as to vary the devices' responses to electromagnetic radiation of varying frequencies on demand, for example in respond to changing energies and wavelengths of incident radiation. Alternatively, the devices' responses to electromagnetic radiation can be statically established by methods and described herein.

There are many applications of the devices and methods herein. For example, cities can integrate the devices herein into the walls and roofs of buildings to generate their electrical power requirements. The devices' high solar energy collection efficiencies can enable commercial application of solar energy in high energy density applications suitable for transportation, portable electronic devices, satellites, and other applications. In addition, since the devices herein can at times convert infrared radiation (heat) into electrical power, they can also be used in cooling applications suitable for transportation vehicles, portable electronic devices, and other applications where thermal energy is to be reduced or controlled.

### BRIEF DESCRIPTION OF THE DRAWINGS

FIG. 1 is a graph of the spectral power density of solar radiation at the Earth's surface.

FIG. 2 is graph of reflectance (R) and transmittance (T) of silicon from 0.1 to 600 μm wavelenghts. (See Physical Properties and Data of Optical Materials, editor B. J. Thompson, CRC Press, New York, 2007. p. 535.)

FIG. 3 is a graph of reflectance (R) and transmittance (T) for fused quartz from 0.1 to 600 μm wavelenghts. (See Physical Properties and Data of Optical Materials, editor B. J. Thompson, CRC Press, New York, 2007. p. 535.)

FIG. 4 is a graph of reflectance (R) and transmittance (T) for quartz crystal from 0.1 to 1,000 μm wavelenghts. (See Physical Properties and Data of Optical Materials, editor B. J. Thompson, CRC Press, New York, 2007. p. 535.)

FIG. 5 is a graph of reflectance (R) and transmittance (T) for aluminum from 0.1 to 100 wavelenghts. (See Physical Properties and Data of Optical Materials, editor B. J. Thompson, CRC Press, New York, 2007. p. 535.)

FIG. 6 is a graph of absorbance spectra of ZnO thin films. (See Ekem, N., Korkmaz, S., Pat, S., Balbag, M. Z., Cetin, E. N. and Ozmumcu, Some physical properties of ZnO thin films prepared by RF sputtering technique, International Journal of Hydrogen Energy, vol.34, 2009, p. 5218.)

FIG. 7 is a graph of absorbance spectra of CdO thin films. (See Dakhel, A. A., Transparent conducting properties of samarium-doped CdO, Journal of Alloys and Compounds, vol.475, 2009, p. 51.)

FIG. 8 is a graph of reflectance (R) and transmittance (T) for evaporated thin films of Al (T₁-T₃) and for Al thick films (R₁-R₅) from 0.1 to 1,000 μm wavelenghts.

FIG. 9 is a schematic diagram of a unit cell for an exemplary nanotube/nanowire solar collector.

FIG. 10 is a schematic diagram of an exemplary integrated nanotube.

FIG. 11 is a schematic of an exemplary fabrication of multi-walled nanotubes (MWNTs) utilizing a N—Ti (catalyst-electrode) contact layer as described herein.

FIG. 12 is graph of the critical bandgap (E_{g}) of a metallic carbon nanotube (CNT) versus the applied electrical transverse field (ε).

### DETAILED DESCRIPTION OF THE INVENTION

The Earth's energy inputs consist of solar radiation (173,000 TerraWatts) and heat sources from inside the earth—mainly radioactivity (32 TerraWatts), tides (3 terraWatts) and volcanos and hot springs (0.3 terraWatts). The overwhelming majority of the Earth's energy input is due to solar radiation.

The sun radiates from radio waves to gamma rays; in this wide range the visible light spectrum exists. Visible light has a frequency range between 400 to 750×10¹² cycles per second (THz) with a wavelength between 750 to 400×10⁻⁹ m (nm). At a distance of one astronomical unit (approx. 150 million kilometers) the power density of solar radiation is 1366 W/m² which averaged over the earth is 342 W/m². The spectral power density is the distribution of the solar radiation according to frequency, this being as follows:

Infrared and lower (frequency<400 THz, wavelength>750 nm)—46.3%

Visible (400 THz<frequency<750 THz, 400 nm<wavelength<750 nm)—44.6%

Ultraviolet and above (frequency>750 THz, 400 nm<wavelength)—9.1%

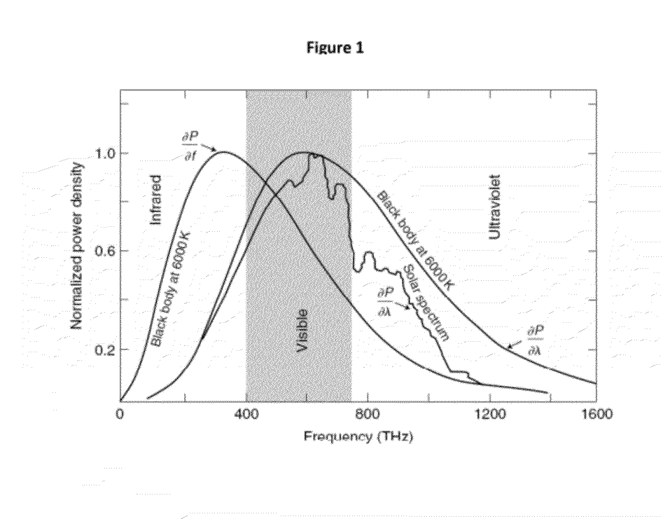

These values are for radiation outside the Earth's atmosphere—the power density of solar radiation on the ground is smaller than in space due to atmospheric absorption. Radiation of frequencies higher than 1,000 THz (wavelength<300 nm) is absorbed by the upper atmosphere. However, this part of the spectrum contains only 1.3% of the solar constant. Still, there is considerable energy to be converted regardless of atmospheric absorption processes. In FIG. 1, the spectral energy density at the surface of the earth according to wavelength is provided.

According to the global energy budget, there is on average globally 168W/m2 of visible energy and 714 W/m2 of infrared energy available (including infrared from the sky and the Earth's surface). (See Geoengineering the climate: Science, Governance and Uncertainty, Royal Society, September 2009, p. 82.) Using the calculations above for energy available from visible or infrared radiation, it is possible to calculate the area required for capture. The results from these calculations are provided in Table 3, where: World Demand represents the total energy mankind needs in that year; Visible represents the area of the earth where visible solar energy equals mankind's needs in that year; Infrared represents the area of the earth where infrared solar energy equals mankind's needs in that year; %Water (Visible) represents the percentage of the Earth's water surface where visible solar energy equals mankind's needs in that year; Dry-Land (Visible) represents the percentage of the Earth's dry-land surface where visible solar energy equals mankind's needs in that year; %Water (Infrared) represents the percentage of the Earth's water surface where infrared solar energy equals mankind's needs in that year; and %Dry-Land (Infrared) represents the percentage of the Earth's dry-land surface where infrared solar energy equals mankind's needs in that year.

TABLE 3
Land use requirements for Visible and Infrared Capture

| | World | | | | | | |
|---|---|---|---|---|---|---|---|
| | Demand | Visible | Infrared | % Water | % Dry-Land | % Water | % DryLand |
| Year | (EJ) | (km²) | (km²) | (Visible) | (Visible) | (Infrared) | (Infrared) |
| 2009 | 0.5021 | 1729566 | 90435 | 0.479 | 1.16 | 0.025 | 0.061 |
| 2015 | 0.5415 | 1865286 | 97531 | 0.517 | 1.25 | 0.027 | 0.065 |
| 2035 | 0.6000 | 2066799 | 108068 | 0.572 | 1.39 | 0.030 | 0.073 |

A concern is that covering a large portion of Earth's land with light-absorbing solar (Photovoltaic) panels will result in a lowering of the Earth's albedo and therefore increase radiative forcing and result in a positive increase in global temperatures. The albedo of an object is the extent to which it diffusely reflects light from light sources such as the Sun. It is therefore a more specific form of the term reflectivity. Albedo is defined as the ratio of diffusely reflected to incident electromagnetic radiation. Albedos of typical materials in the visible light range from up to 90% for fresh snow to about 4% for charcoal, one of the darkest substances. Human activities have changed the albedo (via forest clearance and farming, for example) of various areas around the globe. However, quantification of this effect on a global scale is difficult.

Assuming a scenario in which traditional photovoltaics (PVs) at 28% efficiency account for 50% of the world's energy consumption in 2100 would result in 0.58 million km² or 0.39% of Earth's land area being covered. (See Nemet, G. F., Net Radiative Forcing from Widespread Deployment of Photovoltaics, Environmental Science Technology, vol.43, 2009, p. 2173-2178.) Photovoltaics typically have a real world albedo of between 5-10% (in comparison the albedo of the Earth has been measured at 31%). Therefore, large scale implementation of traditional PV systems would dramatically alter the albedo of visible light on Earth's surface.

In comparison, an infrared solar collector with an efficiency of 90% would require 19 times less surface area and would not alter the albedo of the Earth in the visible light range. Since infrared radiation originates from the Earth's surface and the atmosphere (due to CO₂) there is no alteration in the Earth's energy balance. The reflectivity of visible light with an infrared antenna structure could be adjusted to closely match the Earth's albedo of 31%. Thus, utilizing infrared capture can minimize the surface area on the Earth needed for solar energy collection. In visualizing the needed land use on Earth's surface, the temporally stable lighted areas detectable from space provide a close approximation.

This invention accordingly includes, but is not limited to, a method to collect large amounts of solar energy without changing the albedo of the Earth. The invention also can replace existing solar technologies to reduce heat intake by the earth and reduce the global warming effects of existing solar energy collectors.

This invention also includes, but is not limited to, a solar collector capable of DC electrical output comprising layers of nanotubes/nanowires selected for response to a range of solar radiation wavelengths from infrared to visible and beyond into ultraviolet and higher wavelengths. For example, in some instances the device has the ability to collect the significant amount of energy available from about 650 nm and higher energies. In some instances the device has the ability to collect the significant amount of energy available from about 390 nm and lower energies. The response of the nanotubes/nanowires to electromagnetic radiation of varied wavelengths from infrared to ultraviolet and higher can be accomplished, for example, by choosing nanotubes/nanowires with different bandgaps and nanotubes/nanowires with different diameters. This structure also can include layers of transparent materials that permit solar radiation to pass through for collection on both sides. By fabricating a layered nanotube/nanowire structure designed to capture solar radiation across a wider portion of its spectrum, it can be possible to convert considerably more solar energy.

In some instances, the device also can be designed to adjust frequency response to maximize power output according to the wavelength of electromagnetic radiation present. For example, at different times of the day the solar spectrum varies. When the sun is lower in altitude, scattering in the atmosphere alters the spectrum towards the red end of the spectrum. In addition, since the backside of the substrate can in some instances be exposed to considerable electromagnetic infrared radiation, the device may be able to adjust its frequency/wavelength response according to the transparency of the substrate materials.

The device can in some instances be advanced by the modulation of individual groups of nanotubes/nanowires to capture a wide range of electromagnetic radiation from ultraviolet into the infrared spectrum. In other words, different areas of the device can be provided different modulation voltages to adjust the bandgap and therefore response to the electromagnetic spectrum incident on the device. Therefore, the device can use electrically isolated areas containing nanotubes/nanowires that possess differing bandgaps due to different applied gate voltages. The optical properties of these transparent conductors can be matched to the photovoltaic response of the modulated nanotubes/nanowires.

The invention also includes, but is not limited to, the use of nanowires in place of or in combination with nanotubes to collect solar energy. A nanowire is a structure with a diameter of tens of nanometers or less and an unconstrained length. At these dimensions quantum effects are important. Many different types of nanowires exist including metallic (e.g., Ni, Pt, Au, etc.), semiconducting (e.g., Si, InP, GaN, etc.) and insulating (e.g., SiO₂, TiO₂). Nanowires possess aspect ratios, for length to width ratios, in excess of 1000:1, and it is for this reason that they are referred to as one-dimensional (1-D) materials. Electrons in nanowires are quantum confined laterally and therefore occupy energy levels that are different from the traditional continuum of energy levels found in bulk materials.

Exemplary devices according to the invention can be made using a variety of materials.

For example, nanowires have been synthesized consisting of the binary group III-V materials (GaAs, GaP, InAs and InP), ternary III-V materials (GaAs/P, InAs/P), binary II-VI compounds (ZnS, ZnSe, CdS and CdSe)and binary SiGe alloys. (See Duan, X. and Lieber, C. M., General synthesis of compound semiconductor nanowires, Advanced Materials, vol.12, no.4, 2000, p. 298.) Examples of wide-bandgap nanowires for application in UV to blue wavelengths consist of ZnO(3.37 eV), CdO—ZnO(3.0 eV), MgO—ZnO(4.0 eV) and GaN, InN(0.7-0.8 eV). (See Pearton, S. J., Norton, D. P. and Ren, F., The promise and perils of wide-bandgap semiconductor nanowires fro sensing, electronic and photonic applications, small, vol.3, no.7, 2007, p. 1144.) The nanowires have diameters varying from three to tens of nanometers, with lengths extending tens of micrometers. The synthesis of this wide range of semiconductor nanowires can be extended to many other materials (refer to Table 5).

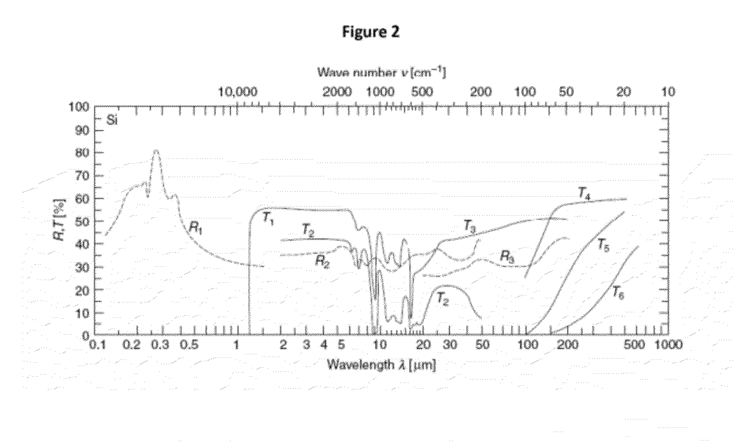

The devices herein also can be fabricated using silicon. In FIG. 2 the transmittance and reflectance of silicon is displayed. (See Physical Properties and Data of Optical Materials, editor B. J. Thompson, CRC Press, New York, 2007, p. 535.) There is a range from wavelengths of approximately 1 to 10 μm in which about 55% of incident infrared radiation is able to transmit through Si samples 2.5 mm thick. If fabricated on silicon master slices of less than 100 μm or 0.1 mm, the transmittance can be higher than 90%.

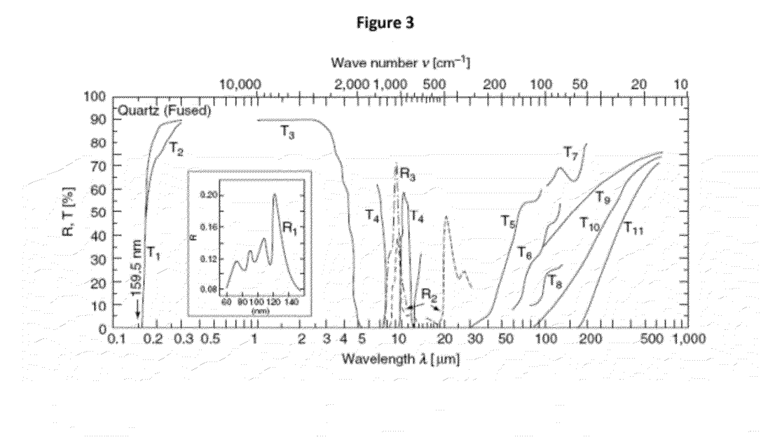

Optional in the application of silicon based substrates is the inclusion of SiO₂ or quartz. The spectral transmittance and reflectance information for fused quartz is provided in FIG. 3. There is close to 90% transmittance of wavelengths between 0.2 to 4 μm for samples 6.46 and 2 mm thick. It is expected that the SIO₂layer would be less than 100 nm/0.1 μm thick, therefore the transmittance value is close to 100% in this wavelength range. In addition, there are transmittance peaks centered at approximately 10 μm wavelength and from 30 μm onward there is increasing transmittance.

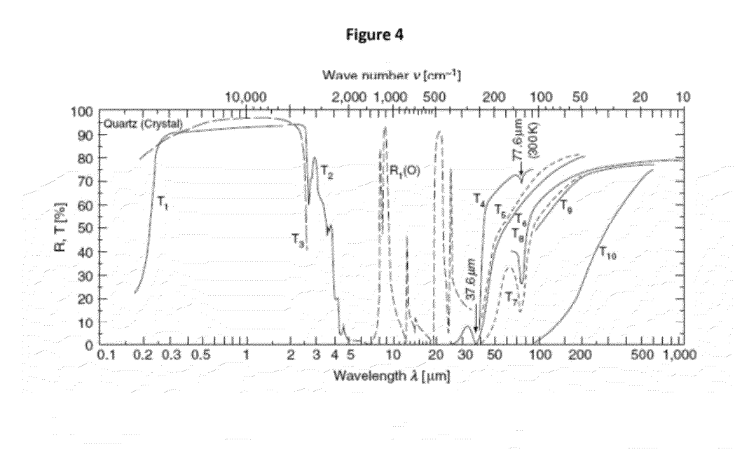

In FIG. 4 the transmittance and reflectance for crystalline quartz is provided. The transmittance for a 2 mm thick sample is over 95% from 0.2 to 2 μm wavelength. There also appears to be more transmittance from 30 μm wavelength and higher in comparison to fused quartz. Depending on the process utilized for creation of the SiO₂ layer, the optical properties are very similar with a slight advantage towards using crystalline quartz. Optionally, the SiO₂ layer may be very thin in comparison to the samples used in the acquired optical data; therefore considerably higher transmission values can be achieved, for example considerably higher transmission in the region between 2 μm and 30 μm in wavelength.

The transmittance and reflectance of a wide range of other materials is given in Table 4. (See Physical Properties and Data of Optical Materials, editor B. J. Thompson, CRC Press, New York, 2007. p. 535.) There is a large selection of materials that can be utilized in the methods and devices herein, including in pure forms and with the addition of dopants to enhance conductivity or other properties.

TABLE 4
Transmittance/Reflectance of Materials

| | Visible-Transmittance | | Infrared-Transmittance | |
|---|---|---|---|---|
| Material | (range-microns) | | (range-microns) | |
| Al2O3 | 85% | (0.2-0.65) | 85% | (0.650-7) |
| BaF2 | 90% | (0.3-0.65) | 90% | (0.65-15) |
| BaTiO₃ | 0-50% | (0.4-0.65) | 55-70% | (0.65-7) |
| Be | T.B.D. | | 80-0% | (17-70) |
| BeO | T.B.D. | | 75-0% | (2.5-7) |
| Bi | T.B.D. | | 10-0% | (50-60) |
| B | T.B.D. | | T.B.D. | |
| Cd | T.B.D. | | 95-100% | (50-125) |
| CdSe | T.B.D. | | 0-65% | (0.75-3) |
| CdS | T.B.D. | | 60-70% | (1-15) |
| CdTe | T.B.D. | | 40% | (1-25) |
| CaCO₃ | 80% | (0.3-0.65) | 80% | (0.65-2) |
| CaF2 | 95% | (0.4-0.65) | 95% | (0.65-7) |
| CsI | 45-75% | (0.3-0.65) | 75-85% | (0.65-50) |
| Cr | T.B.D. | | T.B.D. | |
| Cu | T.B.D. | | T.B.D. | |
| CuCl | 60-70% | (0.4-0.65) | 70-75% | (0.65-15) |
| Diamond | 70% | (0.25-0.65) | 70-60% | (0.65-500) |
| Gallium | 80-90%-Reflectance | | 100 nm-20 μm | |
| GaSb | 0% | | 45% | (2-20) |
| GaAs | 60% Reflectance | | 50% | (1-4) |
| GaP | 30-60% Reflectance | | 20-0% | (0.65-3) |
| Ge | 70-40% | (0.3-0.65) | 50-40% | (2-20) |
| Ge—Se—Te | 0% | | 60% | (1-20) |
| Glass(Oxides) | 90% | (0.3-0.65) | 90% | (0.65-3) |
| Gold(Au) | Reflectance −> | | +95% | (0.65-100) |
| Indium | 15% | (80 nm) | 0% | |
| InSb | Reflectance-40% | | 40% | (5-30 μm), |
| | | | +70% | (200-400 μm) |
| InAs | Reflectance-40% | | 50% | (4-6 μm) |
| InP | Reflectance-30% | | 50% | (1-1.5 μm) |
| Ir | 20% | (50-100 nm) | 80-95% Reflectance | (1-12 μm) |
| Fe | 30-60% Reflectance | (200-650 nm) | 60-90% Reflectance | (0.65-10 μm) |
| LaF₃ | 90% | (0.2-0.35 μm) | +70% | (20-100 μm) |
| PbF₂ | 100% | (0.3-0.65 μm) | 100% | (0.65-10 μm) |
| PbSe | 70% Reflectance | (0.5 μm) | 20% | (4.5 μm) |
| PbS | 50% Reflectance | (0.4 μm) | 15% | (3.5-6 μm) |
| PbTe | 70% Reflectance | (0.5 μm) | 40% | (4-5 μm) |
| LiF | +90% | (0.25-0.65 μm) | +90% | (0.65-4 μm), |
| | | | 0-60% | (100-500 μm) |
| Lucite | 90-100% | (0.4-0.65) | 95-100% | (0.65-3 μm) |
| (Polymethylmetacrylate) | | | | |
| Mg | 70-90% Reflectance | (0.4-65 μm) | Reflectance | (0.65-15 μm) |
| MgF₂ | +90% | (0.25-0.65 μm) | +90% | (0.65-8 μm) |
| MgGe | 20-70% Reflectance | (0.15-0.65 μm) | 35-20% Reflectance | (0.65-20 μm) |
| MgO | 65-70% | (0.25-0.65 μm) | 70-85% | (0.65-7 μm) |
| Mg₂Si | 50-70% Reflectance | (0.25-0.65 μm) | 45-30% Reflectance | (0.65-15 μm) |
| Mg₂Sn | 40-70% Reflectance | (0.2-0.65 μm) | 50-35% Reflectance | (0.65-30 μm), |
| | | | 90% | (+50 μm) |
| Mercury (Hg) | 70-75% Reflectance | (0.2-0.65 μm) | 75-90% Reflectance | (0.65-15 μm) |
| Mo | 20-70% Reflectance | (100-200 nm) | N.A. | |
| Pt | 35-95% Reflectance | (250 nm-10 μm) | 35-95% Reflectance | (250 nm-10 μm) |
| Polyethylene | n.a. | | 80-95% | (1-50 μm) |
| Potassium | 20-90% Reflectance | (250-650 nm) | 90-98% Relectance | (650 nm-2 μm) |
| KBr | 40-90% | (250-650 nm) | 90% | (650 nm-20 μm) |
| KCl | 75-90% | (250-650 nm) | 90% | (650 nm-15 μm) |
| KDP (Potassium | 65-90% | (250-650 nm) | 90% | (650 nm-1.5 μm) |
| Dihydrogen Phosphate) | | | | |
| KI | 40-80% | (250-650 nm) | 80-85% | (650 nm-20 μm) |
| KaTaO₃ | n.a. | | 70-90% Reflectance | (12-100 μm) |
| SiO₂ (Quartz) | 60-95% | (250-650 nm) | 95% | (650 nm-2.5 μm) |
| | | | 70-75% | (40-100 μm) |
| SiO₂ (Fused Quartz) | 80-90% | (250-650 nm) | 90% | (650 nm-3 μm) |
| Rh | 60-80% Reflectance | (200-650 nm) | 80-98% Reflectance | (650 nm-10 μm) |
| Al₂O₃ + Cr₂O₃ (Ruby) | 40-70% | (250-650 nm) | 70-80% | (250 nm-5 μm) |
| | | | 50-55% | (100-500 μm) |
| Al₂O₃ (Sapphire) | 70-85% | (250-650 nm) | 85% | (650 nm-7 μm) |
| | | | 55% | (40-1000 μm) |
| Se | n.a. | | 60-70% | (1-20) |
| Si | 65-40% Reflectance | (250-650 nm) | 55% | (1.5-8 μm) |
| | | | 40-60% | (30-500 μm) |
| SiC | n.a. | | 50-95% | (1-12) |
| Ag (Silver) | 5-95% Reflectance | (250 nm-650 nm) | 95-100% Reflectance | (650 nm-10 μm) |
| AgCl (Silver Chloride) | 15-40% Reflectance | (250-400 nm) | 75-80% Transmittance | (3-20 μm) |
| Na (Sodium) | 90-95% | (250-650 nm) | 95-100% | (650 nm-2.5 μm) |
| NaCl (Sodium Chloride) | 80-90% | (250-650 nm) | 90% | (650 nm-15 μm) |
| NaF (Sodium Fluoride) | 80-90% | (250-650 nm) | 90-92% | (650 nm-12 μm) |
| MgO*3.5Al₂O₃ (Spinel) | n.a. | | 90-10% | (1-6 μm) |
| SrF2 | 90% | (0.2-0.65) | 90% | (0.65-10) |
| SrTiO3 | 60-70% | (0.4-0.65) | 70-75% | (0.65-5) |
| Teflon | 0-15% | (250-650 nm) | 65-80% | (3-500 μm) |
| Tl (Thallium) | 2-60% Reflectance | (70-250 nm) | n.a. | |
| TlBr (Thallium Bromide) | 0-40% | (500-650 nm) | 40-70% | (650 nm-40 μm) |
| ThalliumBromideChloride | 0-50% | (400-650 nm) | 50-75% | (650 nm-30 μm) |
| (KRS-6) | | | | |
| ThalliumBromideChloride | 0-35% | (500-650 nm) | 35-70% | (650 nm-40 μm) |
| (KRS-5) | | | | |
| TlCl (Thallium Chloride) | 0-40% | (400-650 nm) | 40-75% | (650 nm-20 μm) |
| Sn (Tin) | 2-40% Reflectance | (50-200 nm) | 90-98% Reflectance | (500 nm-15 μm) |
| Ti (Titanium) | 0-60% Reflectance | (50-650 nm) | n.a. | |
| TiO2 (Titanium Dioxide) | 0-65% | (400-650 nm) | 65-70% | (650 nm-4.5 μm) |
| W (Tungsten) | 50-45% Reflectance | (200-650 nm) | 45-15% Reflectance | (650 nm-4 μm) |

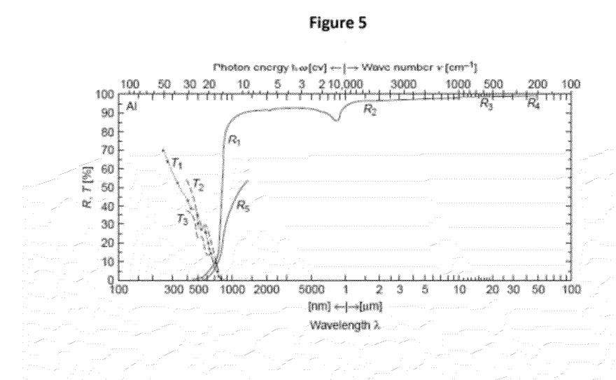

For example, thin layers of aluminum can be coated on the back side of the silicon to charge the gate voltage required for modulation of the bandgap of the nanotubes/nanowires. In FIG. 5 the transmittance and reflectance for aluminum is provided. Aluminum is not transparent to wavelengths of thick film samples (thickness>10-50 μm) with wavelengths longer than about 1000 nm/0.1 μm. Films less than 1 ₖm can have improved transmittance properties. For Al samples of 47, 100 and 138 nm, there is transmittance of between 10-70% of light between 700 to 300 nm. Regardless, aluminum sometimes can interfere with transmission of infrared radiation unless layers less than 1 μm permit significant transmission of infrared.

It is also possible to utilize transparent conductors to control the gate voltage. Aluminum (Al) doped zinc oxide (ZnO) film is a transparent-conducting oxide for use in photo-electronic devices (see Sieber, I., Wanderka, I., Urban, I., Dorfel, I., Schierhorn, E., Fenske, F. and Fuhs, W., Thin Solid Films, vol.330, 1998, p. 108), displays, and in the fabrication of LEDs (see Cho, J., et.al., Japanese Journal of Applied Physics, vol.40, 2001, L1040), and is used as transparent front window layers and back reflector layers for light trapping in thin film photovoltaic cells (see Gardeniers, J. G. E., Rittersma, Z. M. and Burger, G. J., Journal of Applied Physics, vol.83, 1998, p. 7844). Preferable properties of ZnO and other transparent conductors include, but are not limited to: electrical properties such as resistivity and conductivity; optical properties such as optical transmission, refractive index, and band gap; and microstructural properties such as crystal structure, crystal strain, dislocation density, and lattice parameter.

Several techniques can be used to prepare Al doped ZnO films such as evaporation, pulsed laser, metal organic chemical vapor deposition (MOCVD),and magnetron sputtering. These deposition methods can influence the foregoing properties.

Highly conducting Al doped ZnO films have been developed (see Igasaki, Y. and Kannma, Applied Surface Science, vol.169-170, 2001, p. 508; Kluth, O., et.al., Thin Solid Films, vol.124, 1985, p. 43) using radio frequency (RF) magnetron sputtering. Variations of electrical properties of ZnO are also explained by stoichiometry, vacancies and crystallinity. (See Das, Rajesh, Adhikary, K. and Swati, R., Comparison of Electrical, Optical and Structural Properties of RF-Sputtered ZnO Thin Films Deposited Under Different Gas Ambients, Japanese Journal of Applied Physics, vol.47, no.3, 2008, p. 1501.) Resistivity is dependent on carrier concentration, mobility and crystalinity. Low resistivity (2.8×10⁻⁴ Ω-cm) and low sheet resistance (3.5 Ω/square) ZnO can be obtained using magnetron sputtering with C_{H}=10% where C_{H} is given by:

$${C}_{H} = [ \frac{{H}_{2}}{{H}_{2} + {Ar}_{2}} ] \times 100 \qquad Equation 1$$

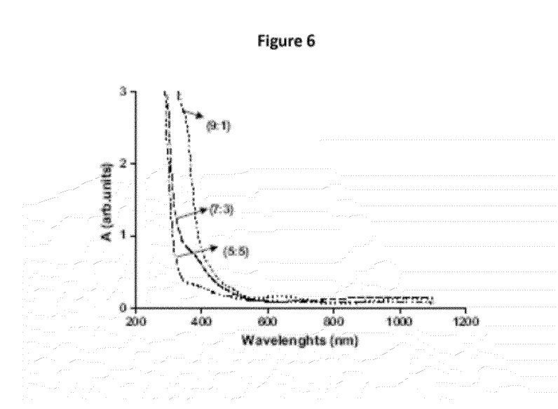

Optical properties of ZnO films shows that absorption at wavelengths higher than 600 nm for ZnO samples is very low (see FIG. 6). There is a sharp increase in absorption at wavelengths below 450 nm.

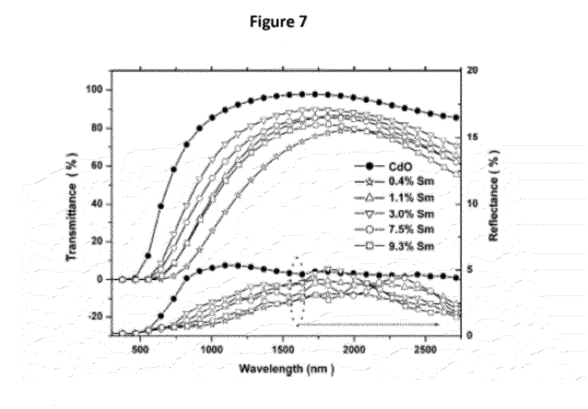

Other examples of doped ZnO thin films consist of Bi-doped ZnO (transmittance above 450 nm rising to 90%) (see Jiang, M., Liu, X. and Wang, H., Conductive and transparent Bi-doped ZnO thin films prepared by rf magnetron sputtering, Surface and Coatings technology, vol.203, 2009, p. 3750), three layered ZnO/Ag—Ti/ZnO structures with sheet resistance of 4.2 Ω/sq, and transmittance of 90% above 400 nm. Transparent magnetic semiconductors consisting of ZnO doped with Co or V into ZnO crystals have been fabricated utilizing laser molecular beam epitaxy for deposition. (See Saeki, H., Matsui, H., Kawai, T. and Tabata, H., Transparent magnetic semiconductors based on ZnO, Journal of Physics: Condensed Matter, vol.16, 2004, p. S5533.) Magnetism has the effect of modulating the band gap of nanotubes/nanowires—therefore magnetic transparent conductors could be utilized to engineer the bandgap of nanotubes/nanowires. Doping of CdO with metallic ions of smaller radius than Cd²⁺ like In, Sn, Al, Sc, and Y improves CdO's electrical conduction properties and increases its optical bandgap energy. (See Dakhel, A. A., Transparent conducting properties of samarium-doped CdO, Journal of Alloys and Compounds, vol.475, 2009, p. 51.) For example, conductive transparent samarium doped CdO displays transmittance of 80-90% from 800 to 2500 nm as shown in FIG. 7. The spectra show that the maxima of spectral transmittance for all films including pure CdO as being in the near infrared (NIR) range. However, resistivity of Sm doped CdO in this work is larger than pure CdO at 10⁻³to10⁻⁴ Ω—cm due to different methods of preparation. Additional transparent oxides consisting of tin and indium oxides (see Gorley, P., et.al., Transparent conductive oxides of tin, indium and cadmium for solar cell applications, Photonics North 2007, Proceedings of SPIE, ed. J. Armitage, vol.6796, 2007, p. 679611X), indium tin oxide (ITO)/metal/ITO multilayer structures where the metal is Ag and Cu (see Guillen, C. and Herrero, J., ITO/metal/ITO multilayer structures based on Ag and Cu metal films for high-performance transparent electrodes, Solar Energy Materials & Solar Cells, vol.92, 2008, p. 938), and high mobility W doped In₂O₃ thin films (see Gupta, R. K., Ghosh, K., Mishra, S. R. and Kahol, P. K., Electrical and Optical Properties of High Mobility W-doped In₂O₃ Thin Films, Materials Research Society Symposium Proceedings, vol.1030, 2008) are candidates for use in the devices herein.

Optically transparent, electrically conductive films of noble metals also can be used. Ultrathin Pt films are a valid alternative to Au (absorption band with a maximum at around 580 nm) since Pt nanoparticles do not absorb over almost the entire UV-vis region—with 70% transmittance in the far-UV region at 260 nm. (See Conoci, S., et.al., Optically Transparent, Ultrathin Pt Films as versatile Metal Substrates for Molecular Optoelectronics, Advanced Functional Materials, vol.16, 2006, p. 1425.) The optical transparency of chromium and nickel ultra thin films is comparable to indium tin oxide (ITO) in the visible and near infrared range (0.4 to 2.4 μm) and significantly higher in the UV range (175-400 nm) and the mid infrared region (2.4 to 25 μm). (See Ghosh, D. S., Martinez, L., Giurgola, S., Vergani, P. and Pruneri, V., Widely transparent electrodes based on ultrathin metals, Optics Letters, vol.34, no.3, 2009, p. 325.) Another technique is to construct solution deposited metal mesh electrodes which possess an optical transparency equivalent to or better than metal oxide films and similar sheet resistance. (See Lee, J-Y., Connor, S. T., Cui, Y. and Peumans, P., Solution-Processed Metal Nanowire Mesh Transparent Electrodes, vol.8, no.2, 2008, p. 689.) In this work Ag was utilized but other conductive metals also can be applied.

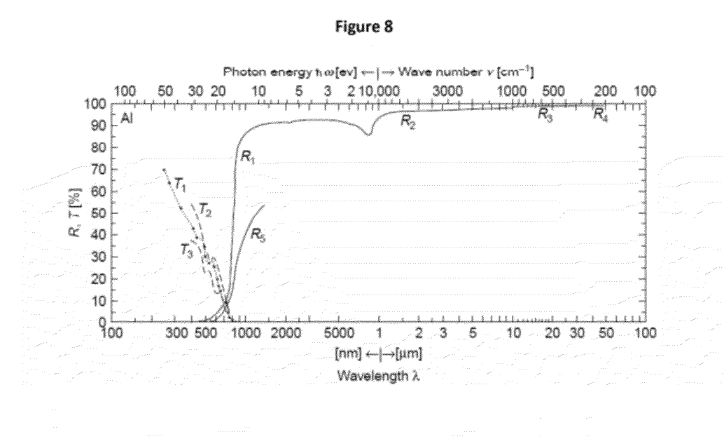

In FIG. 8 the reflectance and transmittance of both Al thin and thick films is provided. Aluminum is opaque in the range from infrared to visible light. There is some transmission at shorter wavelengths into UV range. Otherwise, if transparency with aluminum is required, a design which incorporates apertures evenly spaced can permit transmission of light/infrared radiation.

Factors to consider when designing a nanotube/nanowire is that such devices may not reach ideal efficiency due to a number of loss mechanisms: incident photons are reflected by the cell instead of being absorbed or are absorbed by obstructions such as current collectors; if the thickness of the photoactive material is insufficient, not all photons with energy above band gap energy (Wg) are absorbed—the material may not be opaque enough; not all electron-hole pairs created live long enough to drift to the p-n junction—if the lifetime is small or if they are created far away from the junction, the electron-hole pairs will recombine and their energy is lost; carriers separated by the p-n junction will lose their energy on their way to the output electrodes due to resistance of the connections—this constitutes the internal resistance of the cell; and mismatch between cell and load reduces the complete utilization of the generated power.

Since the Fermi levels of Pd and Al are below and above the Fermi levels of Single Wall Nano Tubes (SWNTs), the p-type and n-type Schottky barriers are formed at the two contacts when no gate voltage is applied. This structure is analogous to a p-i-n junction diode with rectifying I-V characteristics. A p-i-n diode is a p-n junction with an intrinsic layer (i-layer) located between the p-layer and the n-layer. In practice the i-region often consists of either a high resistivity p-layer or a high resistivity n-layer. The p-i-n diode has found wide application in microwave circuits—and can be used in the Terahertz region herein. Specific advantages consist of a wide intrinsic layer that provides properties such as low and constant capacitance, high breakdown voltage in reverse bias, and in use as a vario-losser (variable attenuator) by controlling the device resistance which varies approximately linearly with the forward bias current. The switching time (λₛ) of this diode is given as:

$${τ}_{s} = \frac{W}{2 {υ}_{s}} \qquad Equation 2$$

where W is the width of the intrinsic or i-layer and vₛ is the saturated drift velocity of the slowest charge carrier (i.e. either electrons or holes).

When a photon of energy hv>E_{g} (where his Planck's constant, vis the frequency and E_{g} is the energy gap between the valence and conductance bands)

In the following equation, λ_{g} is the free-space optical wavelength of a photon that has an energy equal to the bandgap of a given material:

λ_{g}=hc/E_{g} Equation 3

The general pattern is that as the atomic weight of a component in a semiconductor increases by moving down a particular column of the periodic table, the bandgap decreases while the refractive index at a given optical wavelength corresponding to a photon below the bandgap increases.

The energy of an electron is a function of its quantum-mechanical wavefactor, k-vector, in the Brillouin zone. In a semiconductor the band gap of a semiconductor is always of two types, a direct band gap or an indirect gap. The minimal-energy state in the conduction band and the maximal-energy state in the valence band are each characterized by certain k-vector. If the k-vectors are the same, it is called a direct band gap; if they are different, it is called an indirect band gap. An indirect band gap requires that an electron cannot shift from the lowest energy state (conduction band) to the highest-energy state in the valence band without a change in momentum from the emission of a phonon (mechanism for transmission of heat) resulting in heat loss. With a direct band gap an electron can shift from the lowest-energy state in the conduction band to the highest-energy state without a change in crystal momentum.

A listing of semiconductors is given in Table 5. A semiconductor can be elemental material or a compound material. Crystalline carbon can take the form of either diamond, which is more an insulator than a semiconductor due to its large bandgap of 5.47 eV at room temperature, or graphite which is a semi-metal. The bandgap of a semiconductor is typically less than 4 eV, and with the exception of some IV-VI compound semiconductors such as lead salts, the bandgap of a semiconductor normally decreases with increasing temperature. Though C is not a semiconductor, Si and C can form the IV-IV compound semiconductor SiC, which has many different structural forms with different bandgaps. Si and Ge can be mixed to form the IV-IV alloy semiconductor SiₓGe₁₋ₓ. These group crystals and IV-IV compounds are indirect-gap materials.

Semiconductors for photonic devices include the III-V compound semiconductors which are formed by combining group III elements such as Al, Ga and In with group V elements such as N, P, As and Sb. In addition different binary III-V compounds can be alloyed with varying compositions to form mixed crystals of ternary compound alloys and quaternary compound alloys. A III-V compound can be either a direct-gap or an indirect-gap material. A III-V compound with a small bandgap tends to be a direct-gap material, whereas one with a large bandgap tends to be an indirect-gap material. The binary nitride semiconductors AlN, GsN, InN as well as their ternary alloys such as INGaN are all direct-gap semiconductors. These direct-gap semiconductors form a complete series of materials that have bandgap energies ranging from 1.9 eV for InN to 6.2 eV for AlN, corresponding to coverage from the visible range to ultraviolet from 650 to 200 nm.

Group II elements such as Zn, Cd and Hg can be combined with VI elements such as S, Se and Te to form binary II-VI semiconductors. Among such compounds the Zn and Cd compounds, ZnS, ZnSe, ZnTe, CdS, CdSe and CdTe are direct-gap semiconductors with large bandgaps ranging from 1.5 eV for CdTe to 3.78 eV for ZnS. The Hg compounds HgSe and HgTe are semimetals with negative bandgaps and HgS with two forms consisting of α-HgS a large-gap semiconductor and β-HgS being a semimetal. The II-VI compounds can be further mixed to form alloys such as HgxCd1-x and HgxCd1-xSe. The ternary II-V alloys include Hg and have a wide range of bandgaps from visible to mid-infrared.

The IV-VI lead-salt compound semiconductors, PbS, PbSe and PbTe as well as their alloys like PbₓSn₁₋ₓTe and PbSₓSe₁₋ₓ are also direct gap semiconductors with bandgaps in the range from 0.145-0.41 eV. These lead salt semiconductors are unusual in that their bandgaps increase with rising temperature, whereas the bandgaps of most semiconductors decrease with increasing temperature.

TABLE 5
Properties of Semiconductors

| | | | Bandgap, | Bandgap, | |
|---|---|---|---|---|---|
| | | | E_{g}(eV) at | E_{g}(eV) at | λ_{g} (nm) at |
| Semiconductor | | Type | 0 K | 300 K | 300 K |
| IV | C (diamond) | Indirect | 5.48 | 5.47 | 227 |
| IV | Si | Indirect | 1.17 | 1.12 | 1110 |
| IV | Ge | Indirect | 0.74 | 0.66 | 1880 |
| IV-IV | SiC | Indirect | 2.39-3.33 | 2.36-3.30 | 380-530 |
| IV-IV | SiₓGe₁₋ₓ | Indirect | 0.74-1.17 | 0.66-1.12 | 1110-1880 |
| III-V | AlN | Direct | 6.29 | 6.20 | 200 |
| III-V | AlP | Indirect | 2.49 | 2.41 | 515 |
| III-V | AlAs | Indirect | 2.23 | 2.17 | 572 |
| III-V | AlSb | Indirect | 1.69 | 1.62 | 768 |
| III-V | GaN | Direct | 3.50 | 3.44 | 360 |
| III-V | GaP | Indirect | 2.34 | 2.26 | 549 |
| III-V | GaAs | Direct | 1.52 | 1.42 | 871 |
| III-V | GaSb | Direct | 0.81 | 0.73 | 1700 |
| III-V | InN | Direct | 1.92 | 1.90 | 653 |
| III-V | InP | Direct | 1.42 | 1.35 | 919 |
| III-V | InAs | Direct | 0.43 | 0.35 | 3540 |
| III-V | InSb | Direct | 0.24 | 0.17 | 7290 |

The work function is one of the fundamental electronic properties of a metallic surface affecting both electron emission through the surface (photoemission, thermionic emission and field emission) and electronic trajectories near the surface (via contact potential differences). Another description of the work function is the minimum energy (usually measured in electron volts) needed to remove an electron from a solid to a point outside the solid surface. For a metal the work function can be separated into surface and bulk contributions. The bulk contribution arises from the free-electron Fermi energy and the exchange and correlation parts of the chemical potential of an infinite uniform electron gas. The surface contribution arises from the relaxation of the electron gas at the metal-vacuum interface. Dependence of the work function on crystalline orientation can be obtained either by considering a corrugated positive background or by reintroducing ion cores as a perturbation on the uniform positive background. The latter procedure results in calculated work function values that agree well with simple metals. There is considerable discrepancy between theory and experiment for the noble metals which can be attributed to orbital electrons. (See Solid State Physics, Lang, N. D., editor Ehrenreich, H., Sitez, F. and Turnbull, D., Academic, New York, vol.28, 1973.) For rare earth metals (i.e. La, Ce, Pr, Nd, Pm, Sm, Eu, Gd, Tb, Dy, Ho, Er, Tm, Yb and Lu) data comparing predicted versus experimental work function values is available. (See Nikolic, M. V., Radic, S. M., Minic, V. and Ristic, M. M., The dependence of the work function of rare earth metals on their electron structure, Microelectronics Journal, vol.27, 1996, p. 93.) The work function of rare earth metals depends on the number of electrons of the most stable f⁷ and f¹⁴ configurations.

Functionality of the devices herein can be affected by the choice in work function values for the source and drain electrodes in comparison to the work function of the nanotube. In Table 6 the work functions of a wide range of elements is provided. (See Michaelson, H. B., The work function of the elements and its periodicity, Journal of Applied Physics, vol.48, no.11, 1977, p. 4729.) Some of the values are calculated assuming that the work function is approximately equal to 2 of the ionization energy in kJ/mol multiplied by a conversion factor equal to 96,472.4 eV*mol/Joule. This should be considered as an approximation with further verification required.

There is an additional approximation for calculating the work function given by the image force Coulomb potential at the metal atomic radius given by:

eΦ=e²/Πε₀r Equation 5

It is also possible to engineer the work function via modulation with a combination of materials listed in Table 6. In its simplest form binary alloys of the form AB could be fabricated, with the addition of ternary alloys of the form ABC and quaternary alloys ABCD if desired.

For the form of an alloy with two metals, A and B, in a proportion X to form a solid solution, with an effective work function,(Wₘ), of a solid solution, AₓB₁₋ₓ can be approximated by:

$${W}_{m} = {xW}_{m , A} + ( 1 - x ) {W}_{m , B} + x ( 1 - x ) [ \frac{( {W}_{m , A} - {W}_{m , B} ) ( {N}_{A} - {N}_{B} )}{{xN}_{A} + ( 1 - x ) {N}_{B}} ] \qquad Equation 6$$

where W_{m,A} and W_{m,B} are the pure constituent work functions of A and B, N_{A} and N_{B} are the pure constituent total density of states of A and B elements and x is the mole fraction of element A.

The density of states at the Fermi energy N(E_{F}) is proportional to the electronic specific heat content, (Cₑ), given by:

$${C}_{e} = ( \frac{1}{3 {Π}^{2}} ) N ( {E}_{F} ) {k}^{2} T \qquad Equation 7$$

where k is the Boltzmann constant and T is the absolute temperature.

Equation 4 can be arranged to:

$${W}_{m} = {W}_{m , B} + ( {W}_{m , A} - {W}_{m , B} ) [ x + \frac{x ( 1 - x ) [ \frac{{N}_{A}}{{N}_{B}} - 1 ]}{x \frac{{N}_{A}}{{N}_{B}} + [ \frac{{N}_{A}}{{N}_{B}} - 1 ]} ] \qquad Equation 8$$

If the ratio of electronic specific heat of elements A and B is approximately 1, then Wₘ changes with x linearly according to the following equation:

Wₘ=W_{B}+x(W_{A}−W_{B}) Equation 9

Caution must be exercised with using this formula in that the specific heats of the elements A and B need to be known to justify a linear relationship. For example Fain and McDavid measured the work function of AgAu alloys and found a non-linear composition dependence. (See Fain, S. C. and McDavid, J. M., Work-function variation with alloy composition: Ag—Au, Physics review B, vol.9, 1974, p. 5099.)

From equation 7 it would be possible to adjust work functions to match the nanotube located in the centre of this device. For example, since Pd is considered to possess favorable properties for attachment to carbon nanotubes, it would be possible to utilize pure Pd on one side and an alloy of Pd with a suitable element forming an alloy. This alloying element could be either lower of higher in work function than Pd.

The work function of pure metals can also be lowered by a monolayer coating utilizing a suitable element or dipole layer of two elements. (See Vacuum Electronics—Components and Devices, editors Eichmeier, J. A. and Thumm, M. K., Springer, Berlin, 2008, p. 535.) For example by the addition of a monolayer of Th on W, the work function of such a system Φ=2.7 eV is far lower than the work function of W of 4.5 eV and even lower than that of Th of 3.5 eV. (See Langmuir, I., The electron emission from thoriated tungsten filaments, Physics Review, vol.22, 1923, p. 357.)

The work function in cold-cathode field emission of materials such as diamond, diamond like carbon or carbon nanotubes can be modulated by doping proper amount of properly selected elements besides the geometric enhancement of emitters. (See Zheng, W. T., Sun, C. Q. and Tay, B. K., Modulating the work function of carbon by N or O addition and nanotip fabrication, Solid State Communications, vol.128, 2003, p. 381.) The work function of N-doped diamond is even lower than the work function of diamond doped with boron and phosphorous. It is possible to lower the work function of carbon nitride films to ˜0.1 eV when deposited at a substrate temperature of 200° C. under 0.3 Pa nitrogen sputtering pressure. Boron nitride coated graphite nanofibers emit electrons at a reduced work function of between 1.5 to 0.8 V/um with high current density.

The electronic work function has also been found to decrease/increase according to tensile/compressive strain in metal samples. (See Zhou, Y., Lu. J. Q, and Qin, W. G., Change in the electronic work function under different loading conditions, Materials Chemistry and Physics, vol.118, 2009, p. 12.)

The presence of minute amounts of contamination (less than a monolayer of atoms or molecules) or the occurrence of surface reactions (oxidation or similar) can change the work function substantially. Changes of the order of 1 eV are common for metals and semiconductors, depending on the surface condition. These changes are a result of the formation of electric dipoles at the surface, which change the energy required by an electron to leave the surface of the material. It is therefore sometimes desirable that the surface of the electrodes are cleaned carefully prior to deposition or attachment of the nanotubes. Several methods are available such as ultrasonic cleaning, chemical cleaning, radio frequency etching, etc.

TABLE 6
Work Function of Elements (eV) data from the CRC Handbook (see Michaelson, H. B.,
The work function of the elements and its periodicity, Journal of Applied Physics, vol. 48,
no. 11, 1977, p. 4729) and the dependence of the work functions of rare earth metals on their
electron structure (see Nikolic, M. V., Radic, S. M., Minic, V. and Ristic, M. M., The dependence of
the work function of rare earth metals on their electron structure, Microelectronics Journal,
vol. 27, 1996, p. 93). Calculations utilized ionization energies (estimation of work function
energy equals approximately one half of ionization energy divided by 96,472.4 eV * mol/Joule),
syn = synthetic and calculated values are marked with the * symbol.

| 1A | IIA | IIIB | IVB | VB | VIB | VIIB | VIIIA | VIII |
|---|---|---|---|---|---|---|---|---|
| H | | | | | | | | |
| (gas) | | | | | | | | |
| Li | Be | | | | | | | |
| (2.9) | (4.98) | | | | | | | |
| Na | Mg | | | | | | | |
| (2.75) | (3.66) | | | | | | | |
| K | Ca | Sc | Ti | V | Cr | Mn | Fe | Co |
| (2.30) | (2.87) | (3.5) | (4.33) | (4.3) | (4.5) | (4.1) | (4.5) | (5.0) |
| Rb | Sr | Y | Zr | Nb | Mo | Tc | Ru | Rh |
| (2.16) | (2.59) | (3.1) | (4.05) | (4.3) | (4.6) | (syn-3.64) | (4.71) | (4.98) |
| Cs | Ba | La | Hf | Ta | W | Re | Os | Ir |
| (2.14) | (2.7) | (3.5) | (3.9) | (4.25) | (4.55) | (4.96) | (4.83) | (5.27) |
| Fr | Ra* | Ac* | Ce | Pr | | | | |
| (liquid) | (2.69) | (2.59) | (2.6) | (2.70) | | | | |
| | | | Th | | | | | |
| | | | (3.4) | | | | | |

| | | | | | | | | | | | | | |
|---|---|---|---|---|---|---|---|---|---|---|---|---|---|
| Ce | Pr* | Nd | Pm | Sm | Eu | Gd | Tb | Dy | Ho* | Er | Yb | Tm | Lu |
| (2.6) | (2.73) | (2.9) | (3.07) | (3.2) | (2.5) | (3.1) | (3.0) | (3.09) | (3.09) | (3.12) | (2.60) | (3.15) | (3.30) |
| Th | Pa* | U | Np | Pu* | Am | Cm | Bk | Cf | Es | Fm | Md | No | Lr |
| (3.4) | (2.94) | (3.6) | (syn) | (3.03) | (syn) | (syn) | (syn) | (syn) | (syn) | (syn) | (syn) | (syn) | (syn) |

| VIIIA | IB | IIB | IIIA | IVA | VA | VIA | VIIA | VIII |
|---|---|---|---|---|---|---|---|---|
| | | | | | | | | He |
| | | | | | | | | (gas) |
| | | | B | C | N | O | F | Ne |
| | | | (4.45) | (5.0) | (gas) | (gas) | (gas) | (gas) |
| | | | Al | Si | P* | S* | Cl | Ar |
| | | | (4.28) | (4.85) | (5.24) | (5.18) | (gas) | (gas) |
| Ni | Cu | Zn | Ga | Ge | As | Se | Br | Kr |
| (5.15) | (4.65) | (4.33) | (4.2) | (5.0) | (3.75) | (5.9) | (liquid) | (gas) |
| Pd | Ag | Cd | In | Sn | Sb | Te | I* | Xe |
| (5.12) | (4.26) | (4.22) | (4.12) | (4.42) | (4.55) | (4.95) | (5.23) | (gas) |
| Pt | Au | Hg | Tl | Pb | Bi | Po* | At* | Rn |
| (5.65) | (5.1) | (4.49) | (3.84) | (4.25) | (4.22) | (4.210 | (4.61) | (gas) |

An aluminum electrode can be sputtered onto the back side of the Si substrate for modulating the SWNT-metal contact barrier. Several choices are available for the synthesis of SWCNTs one of which consists of catalytic chemical vapour deposition (CVD) which produces nanotubes with an average diameter of 0.9 nm (φ=4.5 eV, Eg=1.1 eV). (See Chen, C. X. and Zhang, Y. F., Manipulation of single-wall carbon nanotubes into dispersively aligned arrays between metal electrodes, Journal Physics D: Applied Physics, 2006, vol.39, p. 172.)

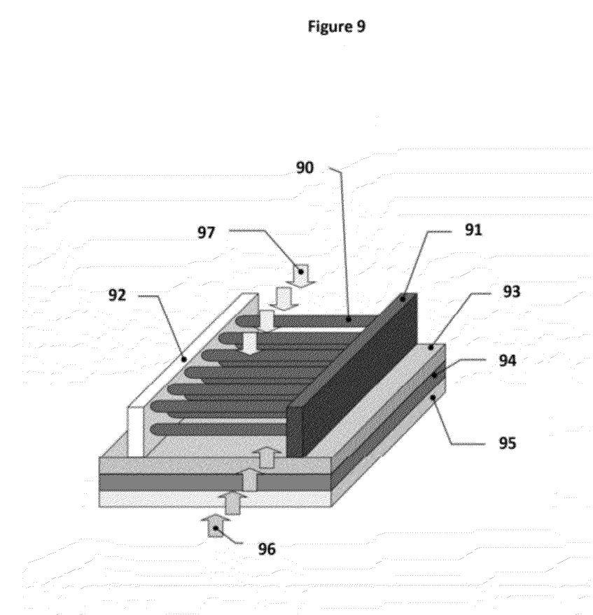

In FIG. 9, an exemplary unit cell of the adjustable nanotube/nanowire solar cell is depicted utilizing a number of nanotubes/nanowires. Semiconducting nanotubes or nanowires 90 are disposed to connect to a source electrode 91 and a drain electrode 92. The semiconducting nanotubes or nanowires convert solar electromagnetic radiation 97 including ultraviolet and infrared frequencies to electrical energy. A supporting matrix for the semiconducting nanotubes or nanowires 90 and source 91 and drain 92 electrodes can optionally be an optically transparent insulating layer 93, optically transparent semiconductive layer 94, and optically transparent electrical contact layer 95. Optical transparency can be desirable to capture solar electromagnetic radiation 96 including ultraviolet and infrared frequencies, such as radiation reflected by the Earth or otherwise.

In some instances, the devices herein comprise nanotubes/nanowires numbering from hundreds to millions of nanotubes/nanowires that can be dynamically controlled with respect to frequency/wavelength of incident electromagnetic radiation. The modulation or variance of gate voltage can control the bandgap of the nanotubes/nanowires. A smaller bandgap alters the response towards longer wavelengths or infrared radiation, whereas a larger bandgap changes the response to shorter wavelengths or ultra-violet wavelengths.

Semiconducting nanotubes such as carbon nanotubes (CNTs) are well suited to photovoltaic applications due to their structural and electrical properties. Carbon nanotubes (CNTs) are well suited due to being almost defect free which results in greatly decreased carrier recombination, posses a wide range of direct bandgaps matching the solar spectrum, display strong photoabsorption and photoresponse from ultraviolet to infrared, and exhibit high carrier mobility and reduced carrier transport scattering. It is possible to fabricate single walled CNTs into photovoltaic cells with high power-conversion efficiency through separation of photogenerated electron-hole pairs. The exemplary device depicted in FIG. 9 can be configured in such a way. For example, Pd and Al electrodes can be utilized with high and low work functions (φ) of 5.1 eV and 4.1 eV. These two electrodes can constitute the drain and source contact electrodes. Carbon nanotubes typically have a work function of 4.5 eV.

A multi-walled carbon nanotube (MWCNT) consists of concentric walls of single walled carbon nanotubes (SWCNT). Since it is known from a probability standpoint that ⅓ of the SWCNT walls are metallic, then there is a very good chance in a MWCNT being a metallic conductor. This would short circuit a nanotube solar convertor.

The devices and methods herein include in some instances the selection of semi-conductor nanotubes to overcome this problem.

For single walled carbon nanotubes (SWCNTs), often ⅓ of the tubes are metallic in nature. It is however possible to utilize an argon radio frequency (RF) plasma to burn off the metallic SWNTs resulting in only semi-conducting SWCNTs and avoid elaborate screening methods for isolation of semi-conducting SWCNTs. (See Chen, B-H., Wei, J-H., Lo, P-Y., Pei, Z-W., Chao, T-S., Lin, H-C. and Huang, T-Y., Novel method of converting metallic-type carbon nanotube field-effect transistors, Japanese Journal of Applied Physics, vol.45b, no.4B, p. 3680.)

In a given sample of SWCNTs there will be a range of diameters resulting in variability of bandgap since the bandgap and tube diameter, d, are related by:

E_{g}=λ(2a/d) Equation 4

where λ is the Π matrix element between adjacent carbon atoms and a is the C—C bond length. The bandgap determines the response of the tube to electromagnetic radiation. Therefore, variability in the diameter of fabricated nanotubes will affect a device's overall frequency response. This can be a problem in designing a cell which needs to convert specific frequencies/wavelengths of electromagnetic radiation into electrical current. An alternative is to utilize a gate voltage to adjust the bandgap of the nanotubes or to use nanowires. In the application of nanowires the bandgap would be fixed according to the material used.

Thus, the devices and methods herein include in some instances the use of a gate voltage to adjust the bandgap of the nanotubes, or the use of nanowires.

Nanotubes possess individual structures, morphologies and properties, which are determined by the method of preparation and further processing. Therefore, a wide variety of synthetic methods have been developed to produce the desired materials and properties for specific technological applications.

The growth of high-quality and milligram quantities of multiwall carbon nanotubes (MWNTs) (see Ebbesen, T. W., Ajayan, P. M., Large-scale synthesis of carbon nanotubes, Nature, vol.358, 1992, p. 220) and single-walled nanotubes (SWNTs) (see Bethune, D. S., Kiang, C. H., DeVries, M., Gorman, G., Savoy, R., Vasquez, J. and Beyers, R., Cobalt-catalyzed growth of carbon nanotubes with single-atomic layer walls, Nature, vol.363, 1993, p. 605; Thess, A., et.al., Crystalline ropes of metallic carbon nanotubes, Science, vol.273, 1996, p. 483) enable the study of intrinsic properties of nanotubes. Several methods are available for bulk production of high-quality carbon SWNT (see Carbon Nanotubes, ed. A. Jorio, G. Dresselhaus and M. S. Dresselhaus, Springer-Verlag, Berlin Heidelberg, 2008, p. 709); the main methods include arc discharge, laser ablation and chemical vapor deposition (CVD) (see Terrones, M., Jorio, A., Endo, M., Rao, A. M., Kim, Y. A., Hayashi, T., Terrnes, H., Charlier, J. C., Dresselhaus, G. and Dresselhaus, M. S., New direction in nanotube science, Materials Today, October-2004, p. 30). However, herein the organization of carbon nanotubes onto a surface is sometimes desired.

Other methods of nanotube synthesis methods include carbothermal, solid-phase, chemical, electron irradiation, membrane-template, and sol-gel for the formation of non-carbon (inorganic) nanotubes. These nanotubes are based on boron nitride and carbonitrides, transition metal sulfides, halogenides, and oxides. (See Pokroppivny, V. V., Non-carbon Nanotubes (Review). I. Synthesis Methods, Powder Metallurgy and Metal Ceramics, vol.40, no.9-10, 2001, p. 485.) Examples of these materials include alloyed carbon nanotubes such as CₓB_{y}N_{y}, C₂BN, C₃B, C₃N₄, carbon nanotubes encapsulating metals, carbides B₄C, chlorides FeCl₃ and other compounds. Also, joints and heterojunctions of C—NT with other nanotubes, nanotubes based on boron nitride (BT-NTs), dichalcogenides of transition metals MeX₂ (where Me=Mo, W, Nb, and X=S, Se, Te), halogenides (e.g. NiCl₂), non-carbon coatings on whiskers or nanofibers (e.g. SiC—SiO₂—BN), quasi-one dimensional colonies and arrays of nanotubes and two-dimensional crystals of these.

The fabrication of tubular nanostructures normally requires layered, anisotropic or pseudo-layered crystal structures which inorganic tubes typically do not possess. Recently methods have been developed for the synthesis of nanotubes which do not have layered structures. (See Yan, C., Liu, J., Liu, F., Wu, J., Gao, K. and Xue, D., Tube Formation in Nanoscale Materials, Nanoscale Research Letters, vol.3, 2008, p. 473.) For example, CuO nanotubes have been synthesized utilizing thermal oxidation based on a gas-solid reaction. Nb₂O₅ nanotubes have been prepared utilizing a sacrificial template strategy based on liquid-solid reaction. And an in-situ template method has been utilized in the fabrication of ZnO taper tubes through the application of chemical etching. Carbon nanotubes have been fabricated using various methods including arc discharging , laser vaporization hydrocarbon pyrolysis and chemical vapor deposition (CVD)

There are several studies devoted to generating nanotubes from most kinds of materials. (See Xiong, Y., Mayers, B. T. and Xia, Y., Some recent developments in the chemical synthesis of inorganic substances, Chemical Communications, 2005, p. 5013; Avramov, I., Kinetics of growth of nanowhiskers (nanowires and nanotubes), Nanoscale Research Letters, vol.2, 2007, p. 235; Piao, Y., Kim, J., Bin-Na, H., Kim, D., Baek, J. S., Ko, M. K., Lee, J. H., Shoukouhimehr, M. and Hyeon, T., Wrap-bake-peel process for nanostructural transformation from B—FeOOH nanorods to biocompatible iron oxide nanocapsules, Nature Materials, vol.7, 2008, p. 242.) Materials such as BN, V₂O₅, NiCl₂, TiO₂ and other materials can be fabricated as tubular structures (see Li, Y., Wang, J., Deng Z., Wu, Y., Sun, X., Yu, D., and Yang, P., Bismuth Nanotubes: A Rational Low-Temperature Synthetic Route, Journal of American Chemical Society, vol.123, 2001, p. 9904; Hacohen, Y. R., Grunbaum, E., Tenne, R., Sloan, J. and Hutchison, J. L., Cage structures and nanotubes of NiCl2, Nature, vol.395, September-1998, p. 336; Chopra, N. G., Luyken, R. J., Cherrey, K., Crespi, V. H., Cohen, M. L., Louie, S. G. and Zettl, A., Boron Nitride Nanotubes, Science, vol.269, August-1995, p. 966; Vega, V., Prida, V., Hernandez-Velez, M., Manova, E., Aranda, P., Ruiz-Hitzky, E. and Vasquez, M., Influence of Anodic Conditions on Self-ordered Growth of Highly Aligned Titanium Oxide Nanopores, Nanoscale Research Letters, 2007, vol.2, p. 355; Liu, F., Sun, C., Yan, C. and Xue, D., Solution-based Chemical Strategies to Purposely Control the Microstructure of Functional Materials, Journal of Material Science Technology, vol.24, no.4, 2008, p. 641; Spahr, M. E., Bitterli, P., Nesper, R., Muller, M., Krumeich and Nissen H. U.). Oxide nanotubes consisting of TiO₂, ZrO₂, SiO₂, TiO₂—NbO₂—BaTiO₃, ZnAl₂O₃, Bi₂O₃, MnO₂, V₂O₅, Co₃O₄, ZnOWO₃, In₂O₃, Ga₂O₃, PbTiO₃ can be fabricated with diameters between 1.4 to 100 nm through template-directed synthesis. (See Bae, C., et.al., Template-Directed Synthesis of Oxide Nanotubes: Fabrication, Characterization, and Applications, Chemical Materials, vol.20, 2008, p. 756.) Other fabrication methods include: electrospinning, anodization, dynamic mineralization, solution based deposition, chemical vapor deposition (CVD), pulsed laser deposition, electrochemical deposition, heat treatments, biomineralization, atomic layer deposition (ALD), solution based deposition, and water-induced vapor deposition. Electrophoretic deposition (EPD) is a traditional process used in the ceramic industry, but also can be utilized in the deposition of inorganic nanoscaled materials. (See Boccaccini, A. R., et.al., The Electrophoretic Deposition of Inorganic Nanoscaled Materials, Journal of the Ceramic Society of Japan, vol.114, no.1, 2006, p. 1.) EPD is achieved through the motion of charged particles dispersed in a suitable liquid towards an electrode under an applied electric field. The deposition of the material occurs via particle coagulation. This technique has been applied to the deposition of nanoparticles, nanotubes, nanorods and related nanoscale structures. EPD can be applied to any solid that is available in the form of fine powder (<30 μm) or a colloidal suspension, including polymers, carbides, oxides, nitrides, and glasses. (See Tabellion, J. and Clasen, R., Journal of Material Science, vol.39, no.3, 2004, p. 803.)

It is possible to integrate nanotube/nanowire structures for the fabrication of nanotube based electronic devices. The main factors with fabrication of single walled nanotubes include diameter, chirality, length and orientation for large-scale integration of nanotube/nanowire devices and circuits. There are two streams of thought for SWNT synthesis and integration:

The production of SWNTs in bulk, followed by purification of the material and dispersion into solution. The reason for purification is that on average only two thirds of the nanotubes are semiconducting; the remaining tubes are metallic. It can be desirable to be able to separate the semiconducting and metallic nanotubes in solution using various techniques (see Arnold, M. S., Green, A. A., Hulvat, J. F., Stupp, S. I. and Hersam, M. C., Sorting carbon nanotubes by electronic structure using density differentiation, Nature Nanotechnology, vol.1, 2006, p. 60; Chattopadhyay, D., Galeska, L. and Papadimitrakopoulos, F., A route for bulk separation of semiconducting from metallic single-walled carbon nanotubes, Journal of the American Chemical Society, vol.125, 2203, p. 3370), or controllable deposition with techniques such as dielectrophoresis (see Krupke, R., Hennrich, F., Lohneysen, H. von and Kappes, M. M., Separation of metallic from semiconducting single-walled carbon nanotubes, Science, vol.301, p. 344; Vijayaraghavan, A., Blatt, S., Weissenberger, D., Oron-Carl, M., Hennrich, F., Gerthsen, D., Hahn, H. and Krupke, R., Ultra-large-scale directed assembly of single-walled carbon nanotube devices, Nano Letters, vol.7, 2007, p. 1556) or molecular recognition (see Keren, K., Berman, R. S., Buchstab, E., Sivan, U. and Braun, E., DNA-templated carbon nanotube field-effect transistor, Science, vol.302, 2003, p. 1380; Wang, Y. H., Maspoch, D., Zou, S. L., Schatz, G. C., Smalley, R. E. and Mirkin, C. A., Controlling the shape, orientation and linkage of carbon nanotube features with nano affinity templates, Proceedings of the National Academy of Sciences of the United States of America, vol.103, 2006, p. 2026). The remaining semiconductive SWNTs are then deposited onto the substrate for device fabrication. To assemble the devices may require spinning of a solution of the CNTs onto pre-deposited electrodes, rather than in-situ growth. This method can sometimes have difficulty with respect to efficient use of substrate area, an economic factor. However, since with this type of fabrication the substrate is not exposed to high temperature, for synthesis of SWNTs, devices could be fabricated on flexible substrates such as plastic.

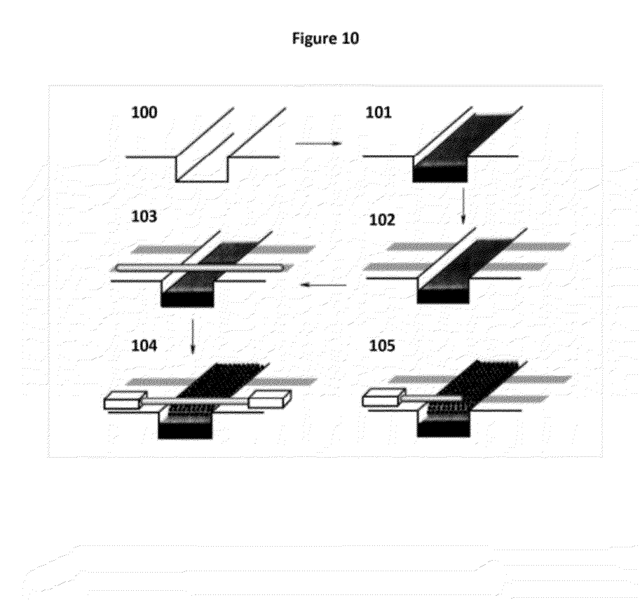

The direct synthesis of SWNTs to specific locations on the surface of the substrate can be achieved through deposition of catalytic materials defined by lithographic methods combined with chemical vapor deposition (CVD). (See Carbon Nanotube Electronics, ed. Javey, A. and Kong, J., New York, Springer, 2009, p. 266.) On the surface of a substrate, nanotubes grow directly from the catalyst layer with good electrical contact achieved by an appropriate choice of an electrode-catalyst film pair. An exemplary sequence for integration of nanotubes onto a planar substrate is displayed in FIG. 10. In 100, a SiO₂ sublayer is etched to fabricate a groove or trench, for example about 20 nm in depth, 100-300 nm in width, and 10 μm in length. In 101, a metal, for example Ti/Au alloy, is placed in the groove or trench. In 102, additional grooves or trenches, for example about 100 nm wide, are etched in the SiO₂ approximately perpendicular to the trench or groove now containing metal. In 103, elongated nanostructures such as nanotubes or nanowires are fabricated and/or attached at the trenches or grooves. 104 and 105 depict alternative final configurations: in 104 with two contacts to the elongated nanostructures, and in 105 with a single contact to the elongated nanostructures. 104 and 105 also depict the adsorption of gas species underneath the nanotubes—this may be excluded according to device requirements. All dimensions and material choices in this fabrication example are adjustable according to device requirements. Candidate film materials include, but are not limited to, Ti, TiN, Au, W, Pt, Pd and Ti/Ag alloy. Cr, Nb, or Ta films, for example, can be utilized as an adhesive sublayer.

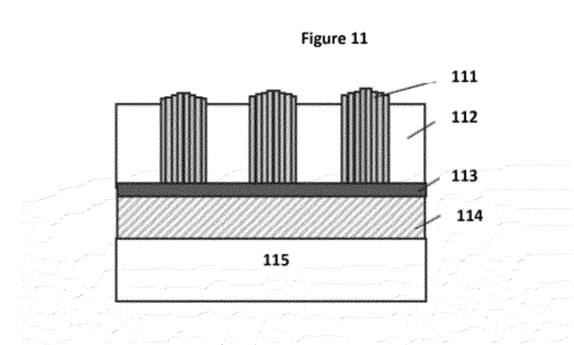

It has been suggested that a thin catalytic layer of Ni (10 nm thick) be deposited onto a contact layer of Ti (100 nm thick). (See Nihei, M., Horibe, M., Kawabat, A. and Awano, Y., Simultaneous Formation of Mutiwalled Carbon Nanotubes and their End-Bonded Ohmic Contacts to Ti Electrodes for Future ULSI Interconnects, Japanese Journal of Applied Physics, vol.43, no.4B, 2004, p. 1856.) In FIG. 11, multi-walled nanotubes (MWNTs) fabricated utilizing a N-Ti (catalyst-electrode) contact layer are shown. A semiconductor substrate 115, for example of silicon, is provided. A contact layer 114, for example Ti approximately 100 nm think, is provided on the substrate 115, and a catalyst layer 113, for example a thin Ni layer, is provided on the contact layer 114. A dielectric layer 112, for example SiO₂ approximately 350 nm thick, also is provided. Channels in the dielectric layer 112 are fabricated, for example, by photolithography, electron beam patterning, and/or nano-patterning, with anisotropic etching. MWNT bundles can be grown or deposited in the channels. All materials and dimensions are adjustable according to the needs of the device, materials available, deposition techniques utilized, etc.

Utilizing a Ni electrode without titanium, a one nanotube bridge exhibited a large resistance of between 15-32 M Ω. A sample with a Ni-Ti electrode displayed a resistance of only 134 kΩ and a three nanotube bridge displayed a resistance of 54 kΩ.

One of the best conducting material for semiconducting CNTs is palladium. (See Zhu, W. and Kaxiras, E., Schotkky barrier formation at a carbon nanotube-metal junction, Applied Physics Letters, vol.89, 2006, p. 243107.) Palladium forms a metal contact with a single-walled CNT completely coated with this metal. An individual semiconducting CNT with such contacts can operate as a metal oxide semiconductor field effect transistor (MOSFET) and as a Schotkky gate field effect transistor.

Single-walled carbon nanotubes (SWCNT) are typically 2 nm in diameter and can be several millimeters in length. Due to the high length/diameter ratio SWCNTs behave like ideal 1-D systems. The tensile strength of SWCNTs is several times that of steel with extremely high thermal conductivity (similar to that of diamond). In addition, the method of preparation can determine whether the nanotube is metallic or semiconducting in nature. This can permit the fabrication of an all carbon device.

It may be preferred in the preparation or deposition of CNTs or nanotubes that only semi-conducting CNTs are utilized since this type of CNT are only sensitive to light and generate electron-hole pairs which contribute to photocurrent.

Another factor is the contact resistance/barrier between CNTs and metal electrodes. With a semiconducting CNT bridged across the electrodes, the barrier height at metal-CNT contact may be too high and block electron-hole pairs generated by IR light at the CNT from entering the metal electrodes.

One of the most attractive properties of CNTs is the relationship between bandgap and diameter of CNTs. The semiconducting bandgap is in the range of sub 100meV to few hundred 100 meV can be controlled through the tube diameter and chirality in the case of single-walled tubes. The bandgap of a CNT is inversely proportional to its diameter with

$${E}_{gap} ∝ \frac{1}{{R}^{2}} .$$

(See Crespi, V. H., Cohen, M. L. and Rubio, A., In Situ Band Gap Engineering of Carbon Nanotubes, Physical Review Letters, vol.79, no.11, 1997, p. 2093.) This semiconducting behaviour and its dependence on diameter make CNTs attractive for application with the infrared spectrum. It is possible to control the bandgap of CNTs, for example, through the fabrication of template channels in which the diameter of CNTs growth is determined. (See Xu, J. M., Highly ordered carbon nanotube arrays and IR detection, Infrared Physics & Technology, vol.42, 2001, p. 485.)

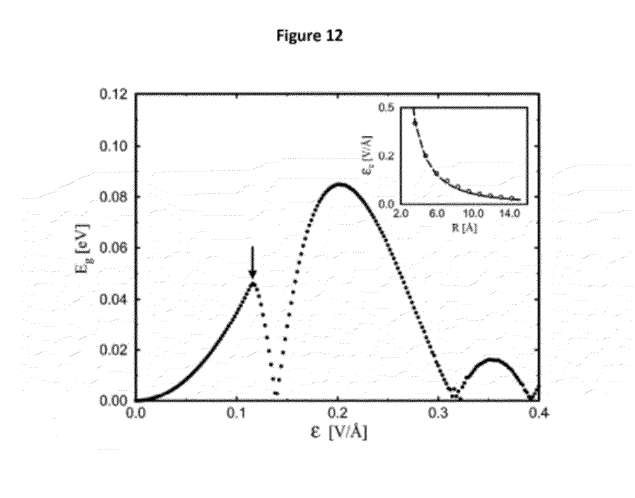

As previously stated, CNTs can demonstrate either semiconducting or metallic conduction depending on the tube diameter and chirality. It is also possible that the bandgap of CNTs can be altered or modulated in a uniform transverse electrical field. (See Li, Y., Rotkin, S. V. and Ravaioli, U., Electronic Response and bandstructure Modulation of Carbon Nanotubes in a Transverse Electrical Field, Nano Letters, vol.3, no.2, 2003, p. 183.) In FIG. 12 a graph is provided displaying the relationship between the transverse field, ε, and the critical bandgap, E_{g} for a metallic CNT.

A similar effect has also been determined for boron nitride nanotubes (BNNTs). Unlike carbon nanotubes which are metallic or semiconducting depending on their helicity/chirality, BNNTs are semiconductors with a theoretical band gap of approximately 5.5 eV. Experimentally observed BNNTs display bandgaps between 4 to 5 eV. (See Czerw, R., Webster, S., Carroll, D. L., Vieira, S. M. C., Birkett, P. R., Rego, C. A. and Roth, S., Tunneling microscopy and spectroscopy of multiwalled boron nitride nanotubes, Applied Physics Letters, vol.83, no.8, 2003, p. 1617.) Theoretical calculations predict that the bandgap of BNNTs can be reduced and, if required, completely eliminated. (See Ishigami, M., Sau, J. D., Aloni, S., Cohen, M. L. and Zettl, A., Observation of the Giant Stark Effect in Boron-Nitride Nanotubes, Physical Review Letters, vol.94, 2005, p. 056804.) In BNNTs the effect of transverse electrical fields is enhanced due to the absence of screening due to the large bandgap. Assuming an intrinsic bandgap of 4.5 eV, a transverse electrical field of 0.1 V/Angstrom reduces the bandgap to 2.25 eV, and a transverse electrical field of 0.19 V/Angstrom eliminates the bandgap completely.

Since there is a variance in bandgap due to strain, stressing the nanotube also can be helpful to its function. Possible methods include: thin films that expand or contract due to heating; electrostatic forces across two electrodes; and piezoelectric thin films that mechanically load/unload stress onto the nanotube.

The foregoing detailed description is provided solely to describe the invention in detail, and is not intended to limit the invention. Those skilled in the art will appreciate that various modifications may be made to the invention without departing significantly from the spirit and scope thereof.

As used throughout this disclosure, the singular forms “a,” “an,” and “the” include plural reference unless the context clearly dictates otherwise. All technical and scientific terms used herein have the same meanings as commonly understood by one of ordinary skill in the art to which this invention belongs, excepting terms, phrases, and other language defined herein.

All publications mentioned herein are cited for the purpose of describing and disclosing the embodiments. Nothing herein is to be construed as an admission that the embodiments described are not entitled to antedate such disclosures by virtue of prior invention. For simplicity, each reference referred to herein shall be deemed expressly incorporated by reference in its entirety as if fully set forth herein.

It is to be understood that this invention is not limited to the particular devices, processes, methodologies or protocols described, as these may vary. It is also to be understood that the terminology used in the description is for the purpose of describing the particular versions or embodiments only, and is not intended to limit the scope of the present invention which will be limited only by the appended claims.

1. A method for converting electromagnetic energy including electromagnetic radiation of ultraviolet and infrared wavelengths into electrical energy, comprising:
exposing one or more elongated nanostructures to electromagnetic radiation, including electromagnetic radiation of ultraviolet and infrared wavelengths;
forming electrons and holes in the elongated nanostructures, including forming electrons and holes as a result of impingement of electromagnetic radiation of ultraviolet and infrared wavelengths on the elongated nanostructures; and
collecting the electrons and holes in the form of electrical current at source and drain electrodes attached to opposite ends of the elongated nanostructures.

2. The method of claim 1, where the elongated nanostructures are semiconducting nanotubes or nanowires.

3. The method of claim 1, where the source and drain electrodes comprise materials of different work functions, the work function of one of the electrodes is less than the work function of the elongated nanostructures, and the work function of the other electrode is more than the work function of the elongated nanostructures.

4. The method of claim 1, where an electrically insulating layer is located to one side of the elongated nanostructures, source electrode, and drain electrode.

5. The method of claim 4, where the insulating layer comprises a material selected from the group consisting of silicon dioxide, insulating polymers, oxides, and ceramics.

6. The method of claim 4, where an electrically conductive layer is located on the side of the insulating layer opposite from the elongated nanostructures and source and drain electrodes.

7. The method of claim 6, where the conductive layer comprises a material selected from the group consisting of silicon, conductive polymers, metals, and metallic oxides.

8. The method of claim 6, further comprising applying a voltage to the conductive layer to modulate the bandgap of the elongated nanostructures and their response to electromagnetic radiation.

9. The method of claim 1, further comprising adjusting the frequency response of the elongated nanostructures by a feedback circuit.

10. The method of claim 1, further comprising exposing the elongated nanostructures to electromagnetic radiation that approaches the elongated nanostructures from opposite sides of the elongated nanostructures.

11. A device for converting electromagnetic energy including ultraviolet and infrared energy into electrical energy, comprising:
one or more elongated nanostructures; and
source and drain electrodes attached to opposite ends of the elongated nanostructures;
where impingement of electromagnetic radiation of ultraviolet and infrared wavelengths on the elongated nanostructures forms electrons and holes in the elongated nanostructures that are collected in the form of electrical current at the source and drain electrodes.

12. The device of claim 11, where the elongated nanostructures are semiconducting nanotubes or nanowires.

13. The device of claim 11, where the source and drain electrodes comprise materials of different work functions, the work function of one of the electrodes is less than the work function of the elongated nanostructures, and the work function of the other electrode is more than the work function of the elongated nanostructures.

14. The device of claim 11, where an electrically insulating layer is located to one side of the elongated nanostructures, source electrode, and drain electrode.

15. The device of claim 14, where the insulating layer comprises a material selected from the group consisting of silicon dioxide, insulating polymers, oxides, and ceramics.

16. The device of claim 14, where an electrically conductive layer is located on the side of the insulating layer opposite from the elongated nanostructures and source and drain electrodes.

17. The device of claim 16, where the conductive layer comprises a material selected from the group consisting of silicon, conductive polymers, metals, and metallic oxides.

18. The device of claim 16, where a voltage applied to the conductive layer modulates the bandgap of the elongated nanostructures and their response to electromagnetic radiation.

19. The device of claim 11, further comprising a feedback circuit that adjusts the frequency response of the elongated nanostructures.
